(19) United States
(12) Patent Application Publication
(10) Pub. No.: US 2006/0024958 A1
(43) Pub. Date: Feb. 2, 2006

(54) HSQ/SOG dry strip process

(76) Inventor: Abbas Ali, Plano, TX (US)

Correspondence Address: TEXAS INSTRUMENTS INCORPORATED, P O BOX 655474, M/S 3999, DALLAS, TX, 75265, US

(21) Appl. No.: 10/903,607

(22) Filed: Jul. 29, 2004

(51) Int. Cl. H01L 21/4763

(52) U.S. Cl. 438/638; 438/637; 438/622; 438/629

(57) ABSTRACT

A spin-on dielectric (120) strip process. Instead of a wet strip, a dry strip process is used to remove the spin-on dielectric (120). In a via-first dual damascene method, a via (116) may be patterned and etched and the via (116) is filled with the spin-on dielectric (120). Then, the trench is patterned and etched while the spin-on dielectric (120) protects the bottom of the via (116). Finally, the spin-on dielectric (120) is removed using a dry strip process with a low ion energy plasma.

### FIELD OF THE INVENTION

The invention is generally related to the field of forming integrated circuits and more specifically to an HSQ/SOG dry strip process that may be used in, for example, a dual damascene process flow for forming interconnect structures.

### BACKGROUND OF THE INVENTION

As the density of semiconductor devices increases, the demands on interconnect layers for connecting the semiconductor devices to each other also increases. Therefore, there is a desire to switch from the traditional aluminum metal interconnects to copper interconnects and from traditional silicon-dioxide-based dielectrics to low-k dielectrics, such as organo-silicate glass (OSG). Semiconductor fabrication processes that work with copper interconnects and newer low-k dielectrics are still needed. As compared to the traditional subtractive plasma dry etching of aluminum, suitable copper etches for a semiconductor fabrication environment are not readily available. To overcome the copper etch problem, damascene processes have been developed.

In a damascene process, the IMD (intrametal dielectric) is formed first. The IMD is then patterned and etched to form a trench for the interconnect line. If connection vias have not already been formed, a dual damascene process may be used. In a dual damascene process, the trench is formed in the IMD and a via is etched in the (interlevel dielectric) ILD for connection to lower interconnect levels. The barrier layer and a copper seed layer are then deposited over the structure. The barrier layer is typically tantalum nitride or some other binary transition metal nitride. The copper layer is then electrochemically deposited using a seed layer over the entire structure. The copper is then chemically-mechanically polished (CMP'd) to remove the copper over the IMD, leaving copper interconnect lines and vias. A metal etch is thereby avoided.

Patterning and etching in a dual damascene process can be problematic due to the necessity of forming both the trench and the via before filling either with copper. Both trench-first and via-first processes are being developed. In a via-first process, the via is patterned and etched followed by the trench patterning. The bottom of the via needs to be protected during the trench etch to prevent etching of the via etch-stop layer. A BARC (bottom-antireflective coating) via fill has been proposed for protecting the bottom of the via during the trench etch. A spin-on organic BARC is often used to reduce substrate reflectivity during resist pattern. This BARC may be used to protect the bottom of the via. Then, after trench pattern and etch, the BARC is completely removed or “stripped”. Methods for effectively protecting the via bottom in a dual damascene process without creating additional processing problems are desired. Moreover, as new technologies demand ever smaller critical dimensions (CDs) in semiconductor devices, CD control becomes more important. Semiconductor processes must be controllable so that the small CDs can be reproduced.

### SUMMARY OF THE INVENTION

The invention is a spin-on dielectric strip process. Instead of a wet strip, a dry strip process is used to remove the spin-on dielectric. For example, in a via-first dual damascene method, a via may be patterned and etched and the spin-on dielectric is deposited in the via. Then, the trench is patterned and etched while the spin-on dielectric protects the bottom of the via. Finally, the spin-on dielectric is removed using a dry strip process.

An advantage of the invention is providing an improved process for removing a spin-on dielectric that minimizes CD blowout.

This and other advantages will be apparent to those of ordinary skill in the art having reference to the specification in conjunction with the drawings.

### BRIEF DESCRIPTION OF THE DRAWINGS

In the drawings:

FIGS. 1A-1G are cross-sectional diagrams of a via-first dual damascene interconnect according to the invention at various stages of fabrication.

### DETAILED DESCRIPTION OF THE EMBODIMENTS

In a via-first dual damascene process, it is desirable to protect the via etch-stop layer during the trench etch. Accordingly, a temporary material may be applied to fill the via and protect the etch-stop layer at the bottom of the via during the trench etch. After trench pattern and etch, the temporary material is stripped from the via. BARC has been proposed as this temporary material. Alternatively, the invention uses a spin-on dielectric, such as HSQ (hydrogen silsesquioxane) or SOG (spin-on glass), as this temporary material.

A process for removing the spin-on dielectric after trench etch should minimally impact the via or trench structure. Wet strip processes can cause CD blow out (a widening of the trench or via) and have insufficient selectivities to adjacent materials. In addition, the wet strip may not result in complete removal of the spin-on dielectric.

In light of the problems with a wet strip of a spin-on dielectric, the invention uses a dry strip process using a low ion energy plasma to remove the spin-on dielectric. A dry strip process with a low ion energy plasma minimizes CD blow out and can be accomplished effectively without impacting any selectivity constraints.

A preferred embodiment of the invention will now be described in conjunction with a via-first dual damascene process using an organo-silicate glass (OSG) as the dielectric. It will be apparent to those of ordinary skill in the art that other low-k dielectrics may alternatively be used. It will also be apparent to those of ordinary skill in the art that the invention may be applied to other strip processes where CD control is critical, such as other dual damascene process flows.

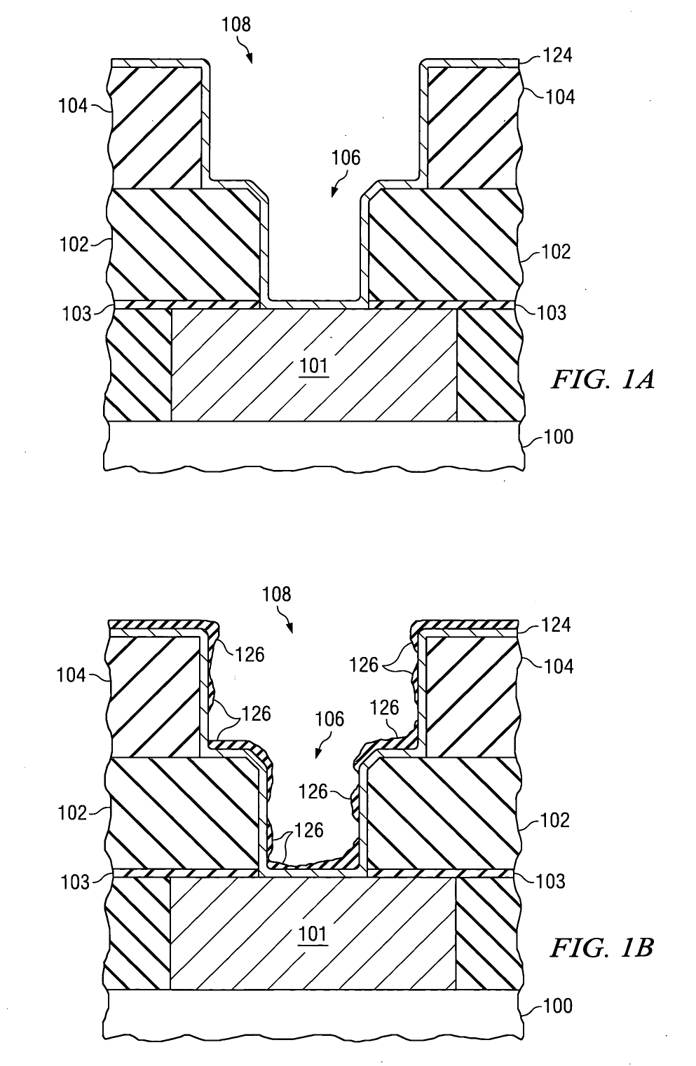

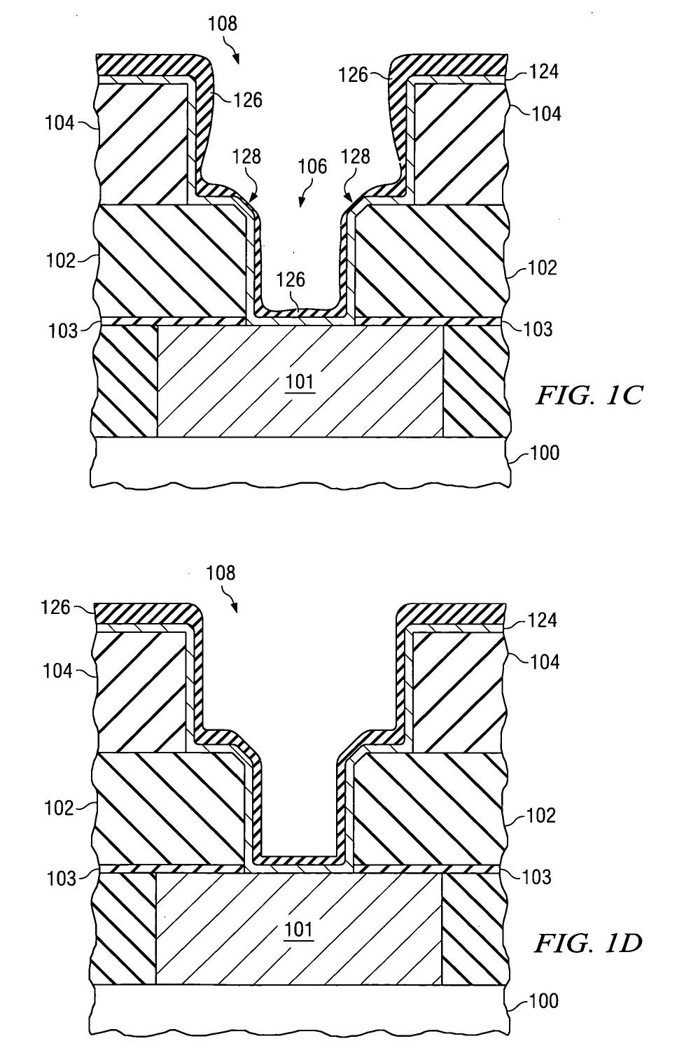

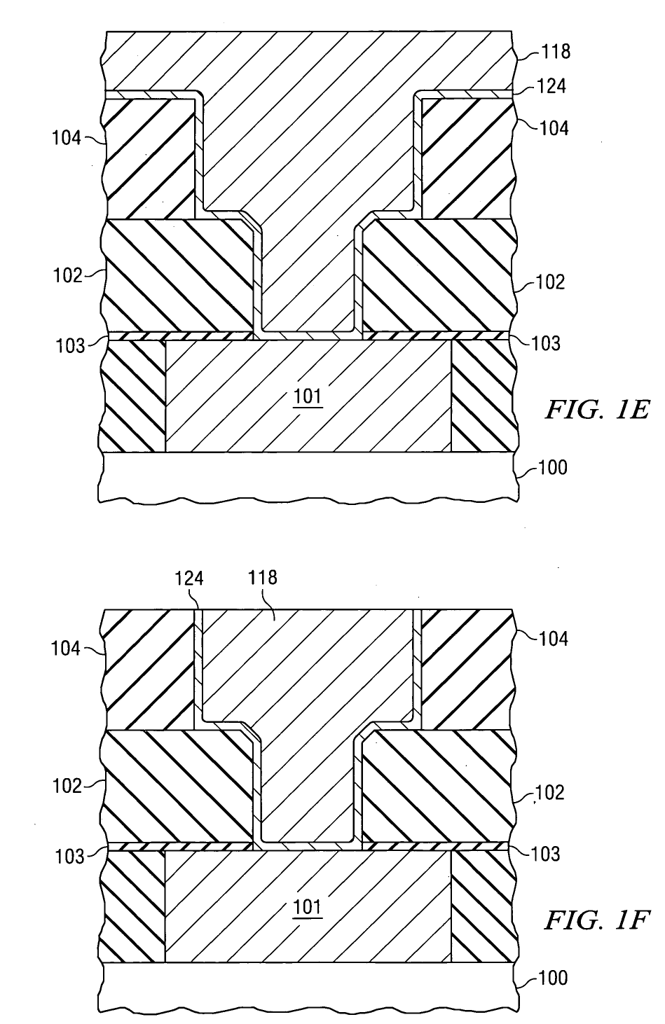

Referring to FIG. 1A, a semiconductor body 100 is processed through the formation of a first interconnect level 102. First interconnect level 102 may in fact be Metal 1 or it may be any metal interconnect level other than the upper most interconnect layer. An etch-stop layer 104 is formed over first interconnect level 102. In the preferred embodiment etch-stop layer 104 comprises silicon nitride. Alternative materials for etch-stop layer 104, such as SiC, are known in the art.

An ILD layer 106 is deposited over etch-stop layer 104. An IMD 110 is deposited over the ILD layer 106. If desired, an etch-stop layer may be formed between ILD 106 and IMD 110. This etch-stop layer may also comprise silicon nitride. ILD 106 and IMD 110 comprise OSG in the preferred embodiment. Alternative dielectric materials, such as FSG (fluorine-doped silicate glass), are known in the art.

Still referring to FIG. 1A, vias 116 are etched in IMD 110 and ILD 106. A resist mask (not shown) is typically used to pattern and etch vias. A hardmask may be optionally deposited on the top of the IMD layer. Appropriate etch chemistries are known in the art. For example, in the case of OSG, the etch of IMD 110 and ILD 106 may comprise C₄F₈/N₂/Ar. The etch chemistry will of course depend on the dielectric (106/110), etch-stop, and hardmask materials used.

Referring to FIG. 1B, a spin on dielectric 120 is deposited to fill vias 116. Spin-on dielectric 120 may comprise a SOG. In a preferred embodiment, spin-on dielectric 120 comprises HSQ. HSQ is a good via plug fill material that may be integrated into a dual damascene process to eliminate via ridge issues. The thickness of the spin-on dielectric 120 is highly dependent upon the via CD, via depth, and via density. For example, a SOG thickness in the range of 100 nm may be needed to achieve a complete via fill across the via topography. Optionally, vias may only be partially filled. However, in a preferred embodiment, a full via fill is utilized to improve process margin in subsequent steps.

The excess portion of SOG may optionally be removed using a plasma etch back with typical chemistries of Ar/C₄F₈/O₂/N₂. If spin-on dielectric 120 is removed from over IMD 110, it may be minimally recessed within vias 116, as shown in FIG. 1C. The etch continues until the sacrificial layer 120 is cleared over exposed portions of IMD 110. After the etch, portions of spin-on dielectric 120 remain in the vias to protect the etch-stop layer 104 during the main trench etch.

Referring to FIG. 1D, a trench pattern 125 is formed over the IMD 110. Various methods are being developed for patterning the trenches and vias in a dual damascene process. For example, the trench pattern 125 may include both a resist mask and a hardmask. The trench etch is then performed to remove the exposed portions of IMD 110, as shown in FIG. 1E. Appropriate etch chemistries are known in the art. For example, in the case of OSG, the etch chemistry may comprise C₄F₈/N₂/Ar.

After the trench etch, the trench resist pattern 125 and any remaining portions of spin-on dielectric 120 are removed as shown in FIG. 1F. A dry strip process with a low ion energy plasma is used to remove spin-on dielectric 120. The low ion energy plasma may be obtained using an RF power in the range of 100-300 W. The low ion energy plasma reduces the physical component of the etch. The desired chemistry uses a gas comprising C, F, H, and/or O elements. For example, a CF₄/Ar chemistry may be used. The chemistry may optionally be combined with N₂, H₂, and/or O₂ to improve CD margin and line edge roughness among other things. Fluorine sources are particularly well suited for etching HSQ. The dry strip process preferably provides a selectivity of at least 5:1 between the spin-on dielectric 120 and the IMD 110/LD 106.

A preferred embodiment uses an RIE (reactive ion etching) tool to provide an anisotropic etch. An exemplary process is given below:
Pressure: 50 mTorr
Power: 100 Watt
Ar flow: 150 sccm
CF₄ flow: 40 sccm
Chuck temp.: 20° C.

The dry strip process may be adapted to also strip the resist of the trench pattern 125. Alternatively, the resist may be wet or dry stripped either before or after the spin-on dielectric 120 dry strip. Removing the pattern 125 during or after the spin-on dielectric dry strip provides additional protection for the IMD 110 during the spin-on dielectric dry strip process.

Next, the via 116 is opened by etching the remaining portion of etchstop layer 104 at the bottom of via 116. Then, the desired barrier layers and copper fill are formed and CMP'd back to form second interconnect layer 126, as shown in FIG. 1G. For example, a TaN barrier may be deposited in trench 124 and via 116 followed by a copper seed layer. Using an electroplating process, the copper fill layer is formed. Then, the copper is chemically-mechanically polished until it is relatively planar with the top of IMD 110. The above process may then be repeated to form additional metal interconnect layers.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

1. A method of fabricating an integrated circuit, comprising the steps of:
depositing a spin-on dielectric over a semiconductor body; and
removing said spin-on dielectric using a dry strip process.

2. The method of claim 1, wherein said dry strip process uses a low ion energy plasma from an RF power in the range of 100-300 W.

3. The method of claim 1, wherein said spin-on dielectric comprises hydrogen silsesquioxane.

4. The method of claim 1, wherein said spin-on dielectric comprises a spin-on glass.

5. The method of claim 1, wherein said step of removing said spin-on dielectric uses an etch chemistry comprising one or more gases selected from the group consisting of C-based gases, F-based gases, H-based gases, O-based gases, and combinations thereof.

6. The method of claim 1, wherein said step of removing said spin-on dielectric uses an etch chemistry comprising CF₄ and Ar.

7. The method of claim 6, wherein said etch chemistry further comprises one or more gases selected from the group consisting of N₂, O₂, and H₂.

8. A method of fabricating an integrated circuit, comprising the steps of:
providing a semiconductor body having a dielectric layer at a surface thereof;
etching a via in said dielectric layer;
depositing a spin-on glass (SOG) layer to fill said via;
forming a trench pattern over said dielectric layer;
etching a trench in said dielectric layer; and
removing said SOG layer using a dry strip process.

9. The method of claim 8, wherein said removing step also removes said trench pattern.

10. The method of claim 8, further comprising the step of removing said trench pattern after the step of removing said SOG layer.

11. The method of claim 8, further comprising the step of removing said trench pattern prior to the step of removing said SOG layer.

12. The method of claim 8, wherein said SOG layer comprises hydrogen silsesquioxane.

13. The method of claim 8, wherein said removing step comprises an etch performed using a low ion energy plasma from an RF power in the range of 100-300 W.

14. The method of claim 8, wherein said step of removing said SOG layer uses an etch chemistry comprising one or more gases selected from the group consisting of C-based gases, F-based gases, H-based gases, O-based gases, and combinations thereof.

15. The method of claim 8, wherein said step of removing said SOG layer uses an etch chemistry comprising CF₄ and Ar.

16. The method of claim 15, wherein said etch chemistry further comprises one or more gases selected from the group consisting of N₂, O₂, and H₂.

17. A method of fabricating an integrated circuit, comprising the steps of:
providing a semiconductor body having an organo-silicate-glass (OSG) layer at a surface thereof;
forming a via pattern over said OSG layer;
etching a via in said OSG layer;
removing said via pattern;
depositing a hydrogen silsesquioxane (HSG) layer to fill said via;
forming a trench pattern over said OSG layer;
etching a trench in said OSG layer; and
removing said HSQ layer using a dry strip process with an RF power in the range of 100-300 W.

18. The method of claim 16, wherein said etching step uses an etch chemistry that comprises CF₄ and Ar.

19. The method of claim 18, wherein said etch chemistry further comprises one or more gases selected from the group consisting of N₂, O₂, and H₂.
